(19) United States
(12) Patent Application Publication
(10) Pub. No.: US 2017/0192830 A1
(43) Pub. Date: Jul. 6, 2017

(54) HIGH-SPEED PSEUDO-RANDOM BIT SEQUENCE (PRBS) PATTERN GENERATOR, ERROR DETECTOR AND ERROR COUNTER

(71) Applicant: Avago Technologies General IP (Singapore) Pte. Ltd, Singapore (SG)

(72) Inventors: Dezhao Bai, Sunnyvale, CA (US); Faouzi Chaahoub, San Jose, CA (US)

(21) Appl. No.: 14/986,347

(22) Filed: Dec. 31, 2015

(51) Int. Cl. G06F 11/07; H03K 3/84; G06F 7/58

(52) U.S. Cl. CPC G06F 11/076; G06F 7/584; H03K 3/84; G06F 11/0709; G06F 2207/581

(57) ABSTRACT

High-speed PRBS-N pattern generator, error detector and error counter circuits are provided that have relatively simple circuit configurations, that quickly synchronize and align the input data with the generated pattern, that easily and quickly detect the occurrence of a bit shifting event, and that quickly resynchronize and realign the input data with the generated pattern after a bit shifting event has occurred. The error counter may be implemented with low-speed circuitry even though the pattern generator and error detector operate at the same speed as the high-speed input data signal. This reduces the complexity and power consumption of the error counter.

### TECHNICAL FIELD OF THE INVENTION

The invention relates to data communications. More particularly, the invention relates to a high-speed Pseudo-Random Bit Sequence (PRBS) pattern generator, error detector and error counter for use in data communications systems.

### BACKGROUND OF THE INVENTION

As communications systems continue to evolve, data is sent at increasingly higher transmission rates. To achieve these transmission rates, the signal-to-noise ratio (SNR) of communications equipment is often lowered to a level where errors become significant. Typically, communications equipment is designed to have a lower bit error rate (BER) than the maximum tolerated BER of a communications system in which the communications equipment operates. Accordingly, the BER of communications equipment is often measured both in production and in-situ to determine if the rates conform to system specifications.

Pseudo-Random Bit Sequence (PRBS)-N patterns are commonly used in BER measurements. PRBS-N patterns are commonly generated by an N-bit digital state machine with known polynomial generation. The pattern length of PRBS-N pattern is 2^{N}−1 bits. For example, a PRBS-7 pattern is a 127-bit long pattern that may be generated with the polynomial X⁷+X⁶+1. The PRBS-15 pattern is 32,767-bit long pattern that may be generated with polynomial X¹⁵+X¹⁴+1.

Devices that perform BER measurements are often referred to as Bit Error Rate Testers (BERTs). FIG. 1 illustrates the basic features of a communications system incorporating PRBS error measurement. The communications system 2 comprises a transmitter 3 coupled to an input of a communications channel such as a fiber optic cable 4 for transmitting a signal, and a receiver 5 coupled to an output of the communications channel 4 for receiving the signal transmitted over the communication channel 4.

PRBS error measurement is implemented in the communications system 2 using two main components: a PRBS-N generator 6 and a PRBS-N error detector 7. The PRBS-N generator 6 creates a signal containing PRBS data. This signal is provided to the transmitter 3, which transmits the signal over the communications channel 4. The receiver 5 receives the transmitted signal containing the PRBS data created by the PRBS-N generator 6, and passes the PRBS data to the PRBS-N error detector 7. The PRBS-N error detector 7 counts the number of bit errors in the PRBS data over time to determine a BER.

Reasons for using a PRBS-N pattern include: (1) the PRBS-N pattern has the same statistical characteristics as a truly random bit sequence; that is, on average there is nearly an equal number of zero value bits as one value bits. When testing communications equipment for bit errors, a truly random sequence is generally a good model for real data; and (2) the PRBS-N pattern is an algorithmically deterministic bit sequence, which means that the next bit in the sequence depends only on the state of the system generating the bit sequence; in other words, it is completely predictable. The PRBS-N error detector 7 uses this characteristic of the PRBS-N pattern to predict the next bit in the received PRBS-N pattern. Any discrepancy between the predicted next bit and the actual received next bit is detected as a bit sequence error in the PRBS-N error detector 7. Such PRBS-N generators and PRBS-N error detectors are known.

FIG. 2 illustrates a block diagram of the known PRBS-N generator 6 shown in FIG. 1 built with a digital finite state machine (FSM). In FIG. 2, a PRBS-7 pattern, of which the generation polynomial is X̂7+X̂6+1, is taken as the example. The devices Q1 12 through Q7 18 are D flip flops, or registers, that are strung together and driven by an input clock CLK to form a 7-bit shift register. The device A1 19 is a mod-2 adder, which is equivalent to an exclusive OR (XOR) gate. After the shift register is started, one bit data per clock cycle is sequentially generated at the DATA output node 21 to create the PRBS-7 pattern.

When the input data at the input node of the error detector 7 shown in FIG. 1 is compared with the output pattern of the local PRBS-N generator 6, the input data bits are checked one by one for every clock cycle. The number of captured bit errors can be counted by the error counter. However, for any valid comparison, the input data has to be synchronized with the generated pattern. First, the clocks driving the input data and the local generator 6 have to be synchronized. This can be easily accomplished by putting the local generator 6 in the same clock domain as the input data latches. Second, the input data pattern has to be aligned with the generated pattern before the comparisons begin. That means that the generator 6 has to be started at the same point of the predefined pattern at the same time as the received input data.

FIG. 3 shows the functional block diagram of a known PRBS-7 generator 28 combined with a PRBS-7 high-speed error detector/error counter 31 and a pattern alignment block 32. Each of the registers Q1 36 through Q7 42 has a reset input R and a set input S. The registers 36-42 can be set to 1 or 0 accordingly by applying set S or reset R, respectively. The devices 45 and 46 are modulo-2 (mod-2) adders, which are the same as XOR gates. The device 47 is an optional clock gating buffer. The INPUT DATA is compared with the DATA′ output from node 51 of the local generator 28 by mod-2 adder 46, and the comparison result ERR is sent to the high speed error detector/error counter 31. The bit error count is available at the output ERROR COUNT of the high-speed error detector/error counter 31.

Before any valid comparison are made, the pattern alignment block 32 sets the initial state of the local generator 28 to a predefined status via the set/reset terminals of the registers 36-42. At the same time, the pattern alignment block 32 takes this predefined status as the starting point of the PRBS-7 pattern and seeks this starting point in the incoming data INPUT DATA. Once the starting point is found in the incoming data, the pattern alignment block 32 either releases the set/reset signal or enables the clock gating buffer 47, or both, depending on the circuit implementation, which starts the local generator 28 at that point. Therefore, the patterns from input data and from the local generator 28 are aligned after the initialization is finished.

Although the high-speed error detector/error counter 31 is relatively straight forward, it has some disadvantages. First, the local pattern generator 28 cannot start until the pattern alignment block 31 finds the predefined starting point in the input data. When the pattern is long, such as a PRBS-31 pattern, for example, a long period of time is required to find the predefined starting point. Second, the pattern alignment block 32 must process the high-speed input data to find the predefined starting point, which leads to the block 32 having very complex circuitry and expensive to implement. This also leads to the high-speed error detector/error counter 31 having very complex circuitry and being expensive to implement because the comparison result is sent directly to the high-speed error detector/error counter 31 to count the number of errors. Because the error signal is a high-speed signal, the high-speed error detector/error counter 31 is required to operate at high speed, which results in it having very complex circuitry. In addition, the complex, high-speed implementation leads to high power consumption. This also limits the feasible length of the high-speed error detector/error counter 31. Fourth, the result output from the high-speed error detector/error counter 31, ERROR COUNT, is usually sent to low-speed digital logic for further processing. The interface needed in order for the low-speed digital logic to read the high-speed signal can be challenging to implement.

FIG. 4 shows a block diagram of another known configuration of PRBS-7 pattern generator and error detector/counter circuitry. In this design, the PRBS-7 pattern generator 41 is modified to work in different modes, and obviates the need for the explicit initialization control described above with reference to FIG. 3. In FIG. 4, registers Q1 12 through Q7 18, and mod-2 adder 19 are same as those of the PRBS-7 pattern generator 6 shown in FIG. 2. The difference is that, in FIG. 4, the input of register Q6 17 comes from INPUT DATA directly rather than from the output of mod-2 adder 19. Because any bit in the PRBS-N sequence is generated from limited previous bits with a known generation polynomial, the value of an incoming bit can be predicted by manipulating the previously received INPUT DATA bits. With the INPUT DATA bits loaded into the altered local generator 41, the expected incoming bit DATA′ is generated at the output of mod-2 adder 19. By comparing the current INPUT DATA bit with the predicted data bit DATA′ in the mod-2 adder 42, any mismatched bits can be caught at the output of mod-2 adder 42.

The local generator 41 in FIG. 4 is initialized by the first few bits of INPUT DATA, so the synchronization process is performed very quickly. For PRBS-N error detector, it requires only N bits of the incoming data being loaded to synchronize with the input data sequence. However, if there are one or more error bits in the INPUT DATA, the error bits will be loaded into the generator and the predicted bit DATA′ will be generated incorrectly. With this incorrectly predicted bit, the comparison result against this bit will also be incorrect. In addition, the error bit will be propagated further such that additional error bits will be in the output DATA′. The consequence is that any one bit error in the input data will generate more than one error bit at the detector output.

Given the generation polynomial is known, such propagated errors may be filtered out with some extra operations. In FIG. 4, the error signal ERR′ at the output of the mod-2 adder 42 is sent to the error filter 43 to obtain an error signal ERR that is free of the propagated false errors. The filtered error signal ERR is then sent to the high-speed error counter 44, which counts the bit errors and generates an error count at its output.

The PRBS-7 pattern generator and error detector/counter circuitry shown in FIG. 4 does not have to be explicitly initialized and can achieve very fast synchronization. Its implementation can also be relatively simple due to the absence of an initialization control block. There are some disadvantages, however. First, the propagated error needs to be removed by the error filter 43 in order for the error count to be accurate. Because the error filter is processing high-speed data and performing a large number of operations, its circuitry can be very complex. In addition, the complexity is increased dramatically for larger values of N.

Second, the PRBS-7 pattern generator and error detector/counter circuitry shown in FIG. 4 is not able to detect the situation when the input pattern has been shifted one or more bits. Bit shifting is a significant error event in many synchronized systems, and the whole data link may have to be reinitialized if it happens. The circuitry shown in FIG. 4 can recover very quickly from a bit shifting event because the synchronization process is based only on N input bits. However, there will be the multiple bit error signals during the resynchronization, and it is very difficult to tell the difference between multiple bit errors and bit shifting.

A need exists for a PRBS pattern generator, error detector and error counter that do not require complex circuitry to implement, that easily detects the occurrence of a bit shifting event, that can be quickly synchronized and aligned with the input data, and that can be quickly resynchronized after a bit shifting event has occurred.

### BRIEF DESCRIPTION OF THE DRAWINGS

FIG. 1 illustrates a block diagram of a known data communications system that incorporates PRBS error measurement technology.

FIG. 2 illustrates a block diagram of the known PRBS-N generator shown in FIG. 1 built with a digital finite state machine.

FIG. 3 illustrates a block diagram of a known PRBS-7 generator combined with a PRBS-7 high-speed error detector/error counter and a pattern alignment block.

FIG. 4 illustrates a block diagram of another known configuration of PRBS-7 pattern generator and error detector/counter circuitry.

FIG. 5 illustrates a block diagram of a high-speed PRBS-N pattern generator, error detector and error counter circuit in accordance with an illustrative embodiment.

FIG. 6 illustrates a state diagram that shows the states of the error trigger block shown in FIG. 5 and the events that cause the error trigger block to transition from one state to another.

FIG. 7 illustrates a block diagram of the error trigger block shown in FIG. 5 in accordance with an illustrative embodiment implemented with a combination of NOR gates and NOT gates.

FIG. 8 illustrates a block diagram of the error trigger block shown in FIG. 5 in accordance with an illustrative embodiment implemented with a combination of a NOT gate, an AND gate, an OR gate, and D flip flop.

FIG. 9 illustrates a block diagram of the digital controller and error counter block shown in FIG. 5 in accordance with an illustrative embodiment.

FIG. 10 illustrates a state diagram that shows the states of the digital controller shown in FIG. 9 and the corresponding states of the control signals.

FIG. 11 illustrates a block diagram of a pattern generator, error detector and error counter circuit in accordance with another illustrative embodiment where N=31 and a generation polynomial of X³¹+X²⁸+1.

FIG. 12 illustrates a block diagram of a pattern generator, error detector and error counter circuit in accordance with another illustrative embodiment in which a half-rate clock is used.

FIG. 13 illustrates a block diagram of a PRBS-7 pattern generator, error detector and error counter circuit in accordance with another illustrative embodiment in which a sub-rate clock is used.

### WRITTEN DESCRIPTION

Illustrative embodiments of high-speed PRBS-N pattern generator, error detector and error counter circuits are described herein that have relatively simple circuit configurations, that quickly synchronize and align the input data with the generated pattern, that easily and quickly detect the occurrence of a bit shifting event, and that quickly resynchronize and realign the input data with the generated pattern after a bit shifting event has occurred. The error counter may be implemented with low-speed circuitry even though the pattern generator and error detector operate at the same speed as the high-speed input data signal. This reduces the complexity and power consumption of the error counter. For illustrative purposes, the high-speed PRBS-N pattern generator, error detector and error counter circuits will be described with reference to illustrative embodiments in which N=7. It should be noted, however, that N may be any value. The reduced complexity of the error counter circuitry provides it with the ability to work with very large N values.

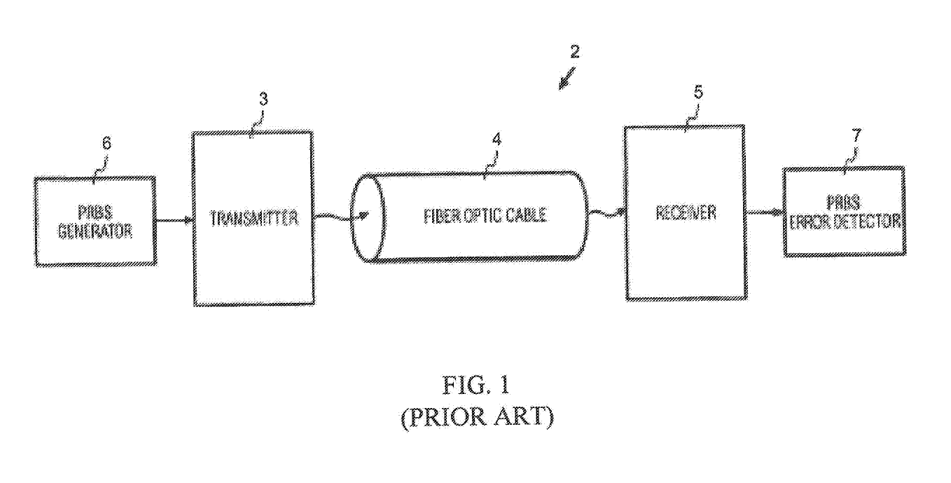

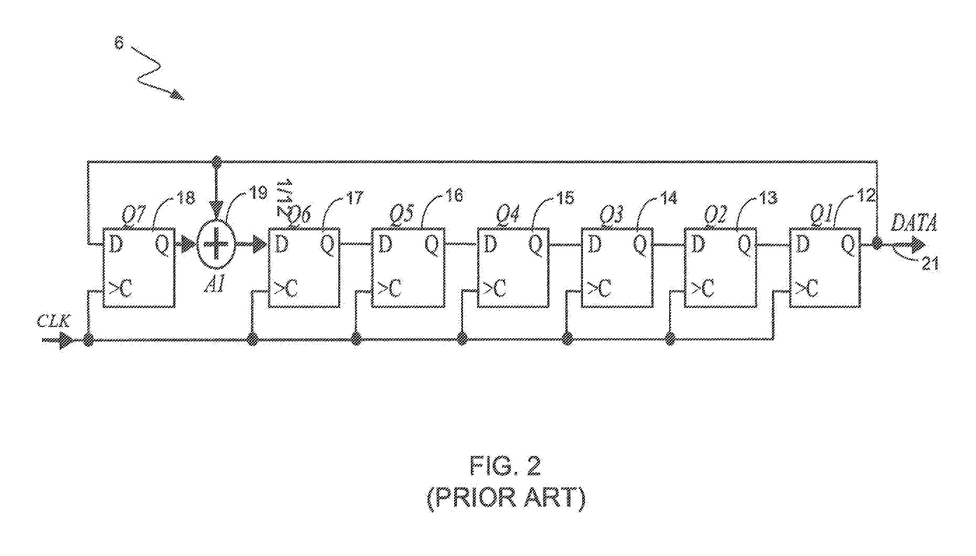

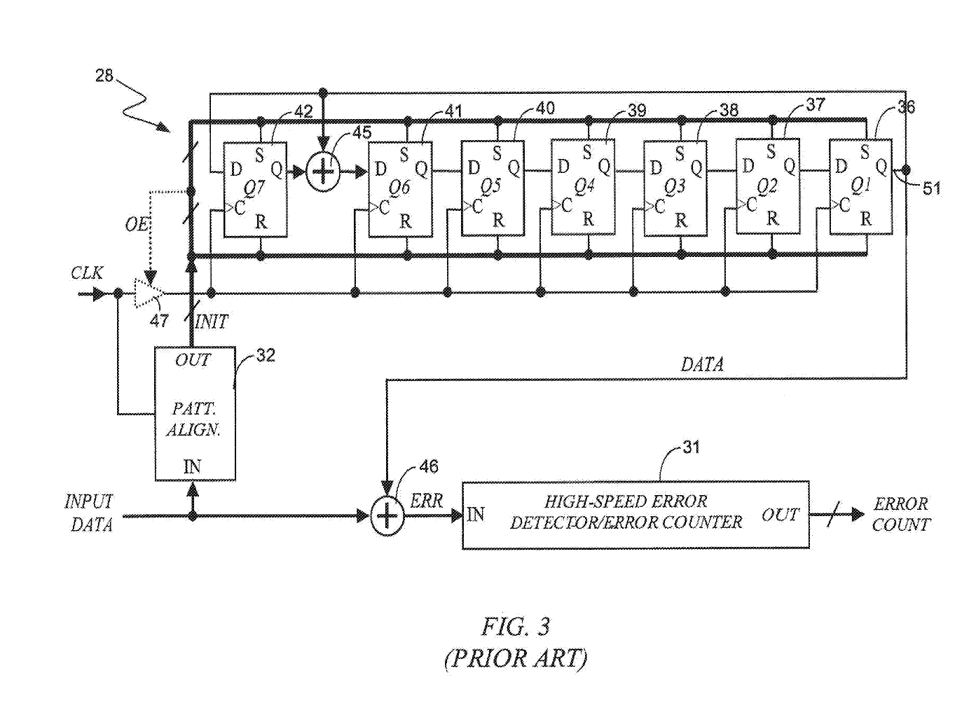

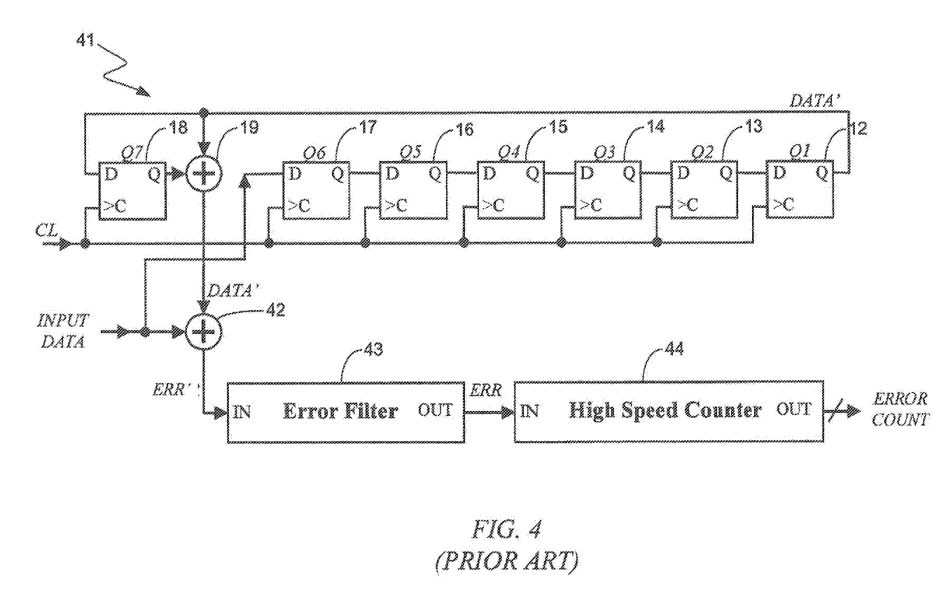

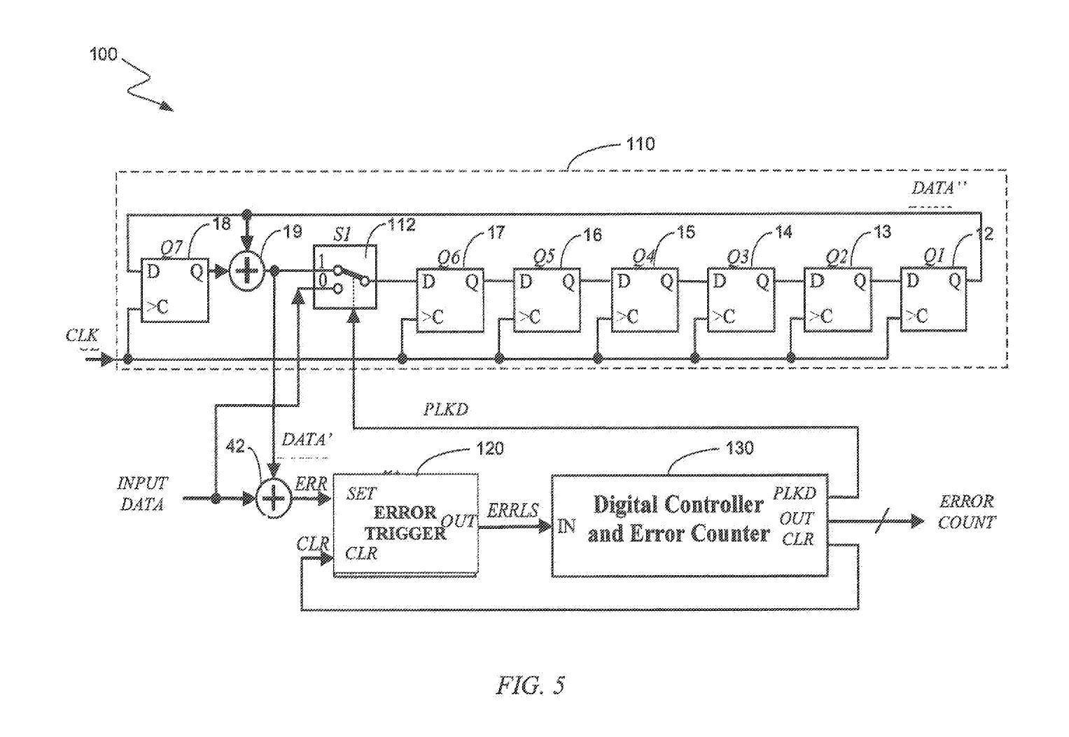

FIG. 5 illustrates a block diagram of a high-speed PRBS-N pattern generator, error detector and error counter circuit 100 in accordance with an illustrative embodiment that may be used in a communications system of the type shown in FIG. 1. However, while the communications channel shown in FIG. 1 is an optical fiber, the communications system of the illustrative embodiments may be an optical communications channel, a wireless communications channel or a wired communications channel. A high-speed PRBS-N pattern generator 110 of the circuit 100 includes registers Q1 12 through Q7 18, which may be the same as the respective devices shown in FIG. 4 having the same reference numerals. The mod-2 adders 19 and 42 may be the same as the respective devices shown in FIG. 4 having the same reference numerals. The PRBS pattern generator 110 includes is a high-speed multiplexer (MUX) 112 that is controlled by a control signal, PLKD. An error trigger block 120 receives the output of mod-2 adder 42, ERR, and generates a signal, ERRLS, which is sent to a digital controller and error counter block 130.

In accordance with this illustrative embodiment, the MUX 112 is located in between the mod-2 adder 19 and the register Q6 17, but in other embodiments it may be located at other positions in the pattern generator 110, as will be described below in more detail. The signal that is output from the MUX 112 is received at the input node of register Q6 17. The MUX 112 has a logic 1 input node and a logic 0 input node. The MUX 112 selects the signal at the logic 1 input node to be output to the input node of register Q6 17 when the state of a control signal PLKD is asserted, which corresponds to a logic 1 state in this illustrative embodiment. The MUX 112 selects the signal at the logic 0 input node to be output to the input node of register Q6 17 when the state of the control signal PLKD is deasserted, which corresponds to a logic 0 state in this illustrative embodiment. The events that cause the state of the control signal PLKD to be asserted and deasserted will be described below in more detail.

In a comparison mode of operations, the value of PLKD is a logic 1 and the multiplexer 112 sends the output of mod-2 adder 19 to register Q6 17. In this mode of operations, the registers Q1 12 through Q7 18 and mod-2 adder 19 are connected to form a typical PRBS-7 pattern generator that generates the correct pattern as the template for the comparison operation. The generated pattern is sent to mod-2 adder 42 to be compared with the incoming data signal INPUT DATA received at the input data port of the circuit 100. Thus, the mod-2 adder 42 acts as a bit error detector to extract a bit error signal ERR for further processing.

Before entering the comparison mode of operations, however, the pattern generator 110 needs to be initialized in order to synchronize and align the input data with the pattern generator 110. In the initialization mode, the value of PLKD is logic 0 and the multiplexer 112 sends the incoming data signal INPUT DATA to register Q6 17. The pattern generator 110 loads the INPUT DATA into its registers Q1 12 through Q7 18, thereby instantly initializing the pattern generator 110 in the same way that the circuitry shown in FIG. 4 performs this process. As long as the correct input data is loaded into the registers Q1 12-Q7 18, the pattern generator 110 will generate a correct pattern that is aligned with the input data. A digital controller and error counter block 130 will switch the pattern generator 110 from the initialization mode to the comparison mode by changing PLKD from 0 to 1 once the initialization process is complete.

In the comparison mode of operations, the error signal ERR output from the mod-2 adder 42 indicates the presence or absence of a bit error of the incoming data INPUT DATA. If any INPUT DATA bit does not match the locally-generated data bit, DATA′, the ERR signal is set to 1 accordingly. If any bit shift happens during the comparison mode of operations, the INPUT DATA and the locally-generated data DATA′ become misaligned and all of the subsequent comparisons become invalid. The consequence is that the BER extracted from the ERR will be extremely high. Such a high BER is very easily detected by the digital controller and error detector block 130. If the digital controller and error detector block 130 detects that the extracted BER is above a predetermined threshold level, it will deassert the control signal PLKD to cause switch the MUX 112 into the initialization mode.

An error trigger block 120 captures any bit error indicated by the error signal ERR and holds the bit error until it has been processed by the digital controller and error counter block 130. This allows the digital controller and error counter block 130 to be implemented with low-speed circuitry, i.e., circuitry that operates at a speed that is lower than the speed of the input data signal and CLK, which are the same speed. The error trigger block 120 has SET and CLR as the input nodes and OUT as the output node.

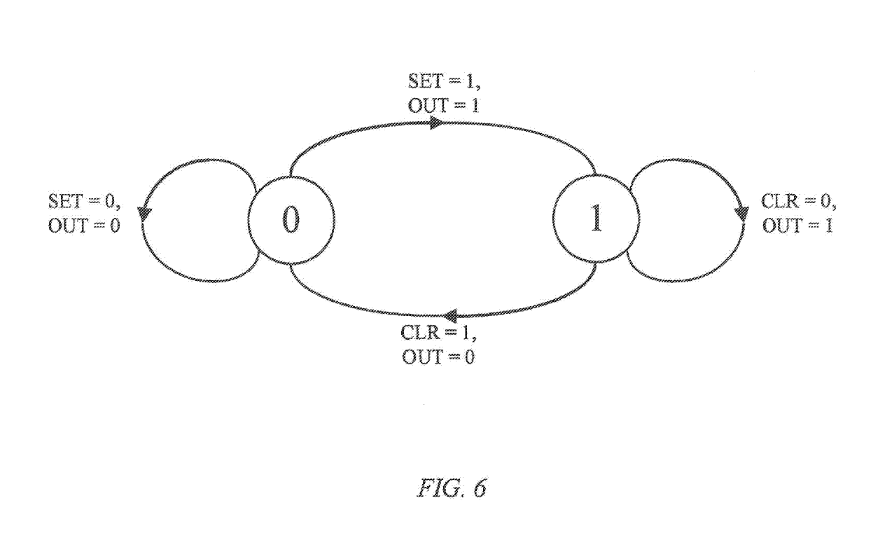

FIG. 6 illustrates a state diagram that shows the states of the error trigger block 120 and the events that cause the error trigger block 120 to transition from one state to another. If the input signal ERR received at the SET input node, is set to logic 1, the state of the error trigger block 120 is set to logic 1 and the error trigger signal, ERRLS, output from the OUT output node is also set to logic 1. If the input signal CLR received at the CLR input node of the error trigger block 120 from the digital controller and error counter block 130 is set to logic 1, the state of the error trigger block 120 is set to 0 and the error trigger signal ERRLS output from the OUT output node of the error trigger block 120 is also set to logic 0.

When there is no error in the INPUT DATA, the error signal ERR remains at logic 0 and the error trigger block 120 is not triggered. When there is an error event in the INPUT DATA, the error signal ERR becomes logic 1, causing the state of the error trigger block 120 and the error trigger signal ERRLS to be set to logic 1. When the error trigger signal ERRLS is received by the digital controller and error counter block 130, the digital controller and error counter block toggles the clear signal CLR to reset the state of the error trigger block 120 to logic 0. The purpose of the error trigger block 120 is to convert the high-speed error signal ERR to the low speed error trigger signal ERRLS. The error trigger block 120 can accomplish this using only a very small amount of high-speed circuitry. The high-speed error signal ERR is sampled and held until the low-speed digital controller and error counter block 130 have processed the bit error.

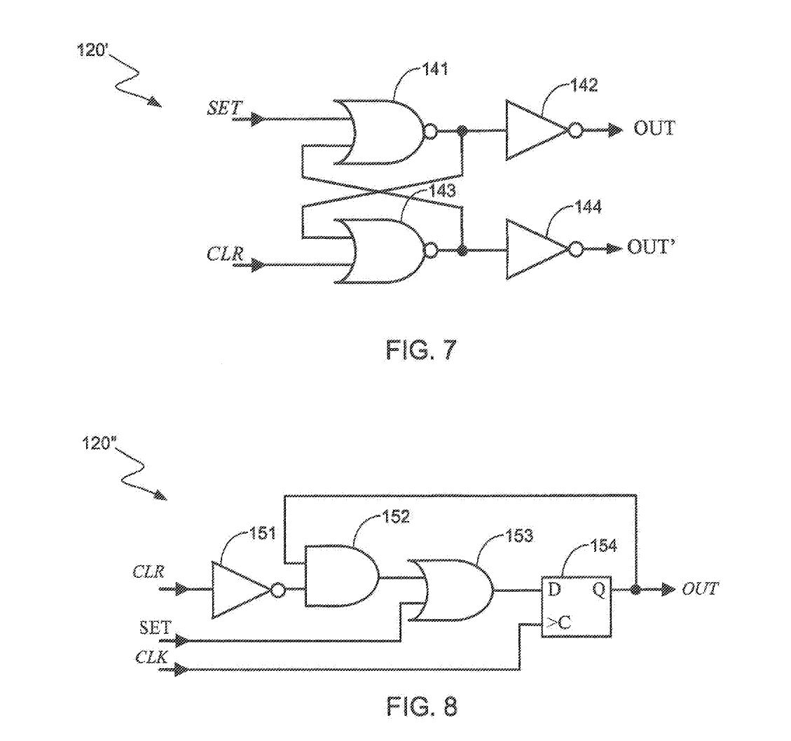

The error trigger block 120 can be implemented in many different ways, as will be understood by those of skill in the art. FIG. 7 illustrates a block diagram of the error trigger block 120′ implemented with a combination of NOR gates 141 and 143 and NOT gates 142 and 144. FIG. 8 illustrates a block diagram of the error trigger block 120″ implemented with a combination of a NOT gate 151, an AND gate 152, an OR gate 153, and D flip flop 154. It should be noted that there are many logical configurations that may be used to achieve the functionality of the error trigger block 120, as will be understood by those of skill in the art in view of the description provided herein. Therefore, the logical configurations shown in FIGS. 7 and 8 are only a few examples of logical configurations that are suitable for this purpose.

The digital controller and error counter block 130 provides all of the control and counting functions for the circuit 100. It receives the low-speed error trigger signal ERRLS from the error trigger block 120, counts the number of bit errors that have been detected, and generates the CLR and PLKD signals based on that input. Each time the digital controller and error counter block 130 processes a bit error and increments the error counter, the CLR signal is toggled to cause the error trigger block 120 and the ERRLS signal to be set to logic 0.

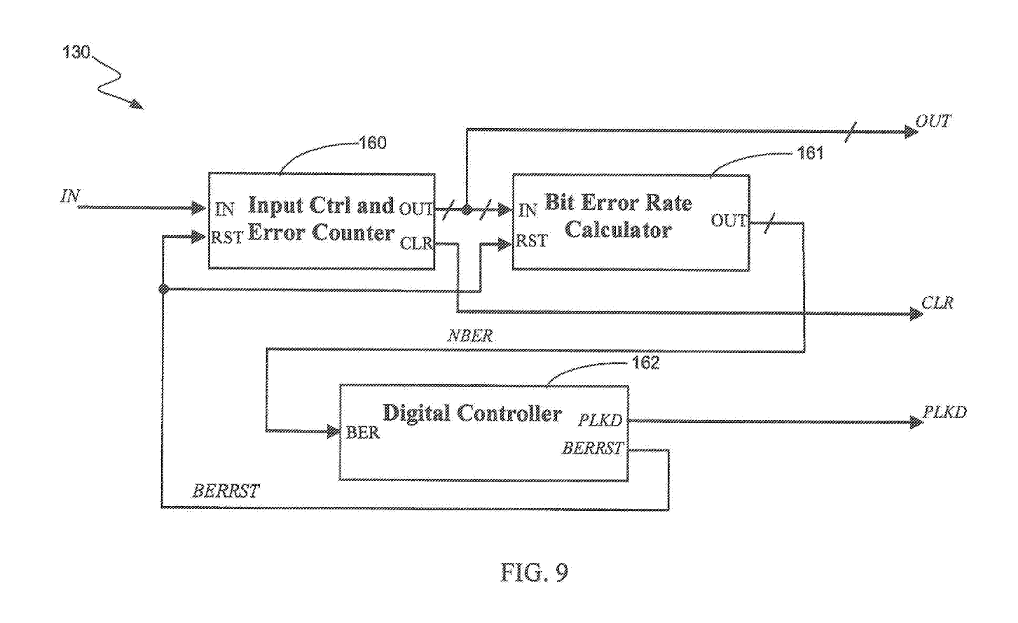

FIG. 9 illustrates a block diagram of the digital controller and error counter block 130 shown in FIG. 5 in accordance with an illustrative embodiment. When the input IN, which is the error trigger signal ERRLS from the error trigger block 120, goes to logic 1, this is an indication that a bit error has been detected. The input control and bit error counter block 160 counts the detected bit error and clears the error trigger clear signal CLR, which is sent back to the error trigger block 120. The counting result OUT of the input control and error counter block 160 is sent to a bit error rate calculator 161, which calculates the BER of the input data.

Based on the BER result, NBER, the digital controller 162 determines its own state and sends control signals BERRST and PLKD to blocks 160 and 161 and to the MUX 112 (FIG. 5). As indicated above, when the BER is above a predetermined threshold value, indicating that a bit shifting event has occurred, the control signal PLKD is asserted to cause the pattern generator 110 (FIG. 5) to re-enter the initialization mode. Once re-initialization has completed, the control signal PLKD is deasserted to cause the pattern generator 110 to re-enter the comparison mode.

It should be noted that the blocks 160-163 may be implemented with a variety of logical configurations. The digital controller 162 is typically a processor programmed with software and/or firmware to carry out the control functions described above. For example, the digital controller 162 may be a microprocessor, a microcontroller, a field programmable gate array, or a digital signal processor (DSP). Any computer code that is executed by the digital controller 162 is stored in a computer-readable medium, which may be on board the digital controller 162 or some other memory device that is external to and accessible by the digital controller 162. Blocks 160 and 161 are typically implemented in hardware in the form of logic gates, but they could instead be implemented in a combination of hardware and software and/or firmware.

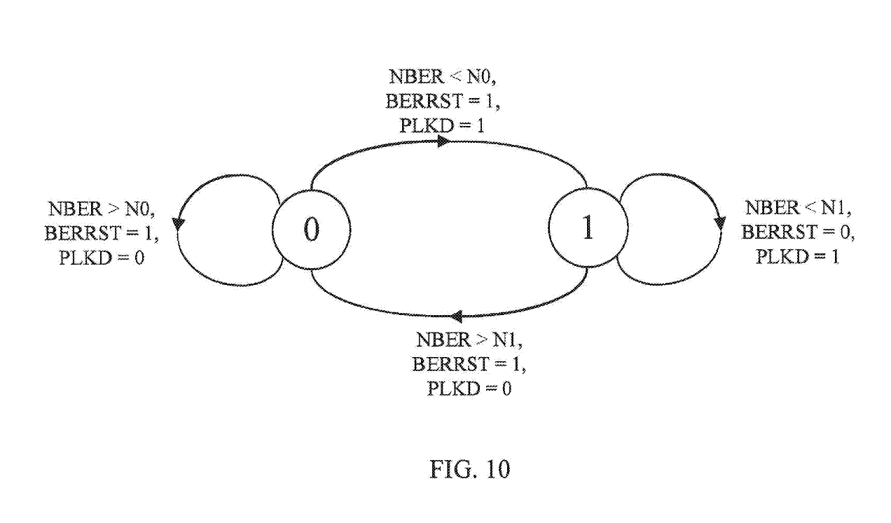

FIG. 10 illustrates a state diagram that shows the states of the digital controller 162 shown in FIG. 9 and the corresponding states of the control signals, NBER, BERRST and PLKD. There are two logical states of the digital controller 162 (FIG. 5), one of which corresponds to the initialization mode of operations and the other of which corresponds to the comparison mode of operations. State 0 is defined as the initialization state, in which the PLKD signal is set to logic 0 to initialize the pattern generator 110. The BER result, NBER, is monitored continuously in state 0. When the extracted BER result NBER is less than a first expected predetermined threshold level, N0, the state will be changed from state 0 to state 1. State 1 is defined as the normal comparison state and the PLKD signal is set to 1, accordingly. The bit error rate calculator block 161 continues to run in this state and the BER result NBER is continuously monitored in this state. When the BER result NBER is higher than a second predetermined threshold level, N1, then this is an indication that either the circuit 100 or the input data has failed. When that happens, the state is changed from state 1 to state 0 to re-initialize the pattern generator 110. This mechanism ensures that the circuit 100 can recover automatically in a very short period of time when a significant error event has occurred, such as bit shifting of the input data.

Because the digital controller and error counter block 130 (FIG. 5) does not directly interface with the high-speed data, it is not required to have a high-speed design, and therefore can be implemented using standard digital circuits. One advantage of this is that the control logic of block 130 can be very flexible and powerful. Another advantage is that the bit error counter of block 130 can be made long enough to meet different requirements of real-world applications. Yet another advantage is that the lower-speed design of block 130 leads to lower power consumption.

Although the proposed PRBS-N pattern generator, error detector and error counter circuit 100 has been described with reference to PRBS-7 patterns for exemplary purposes, the same principles can be easily applied to different lengths of PRBS-N patterns of different generation polynomials. In such other cases, the pattern comparison logic, error processing logic and control logic are similar to those described above, but the pattern generator portion is different due to the different generation polynomial that is used.

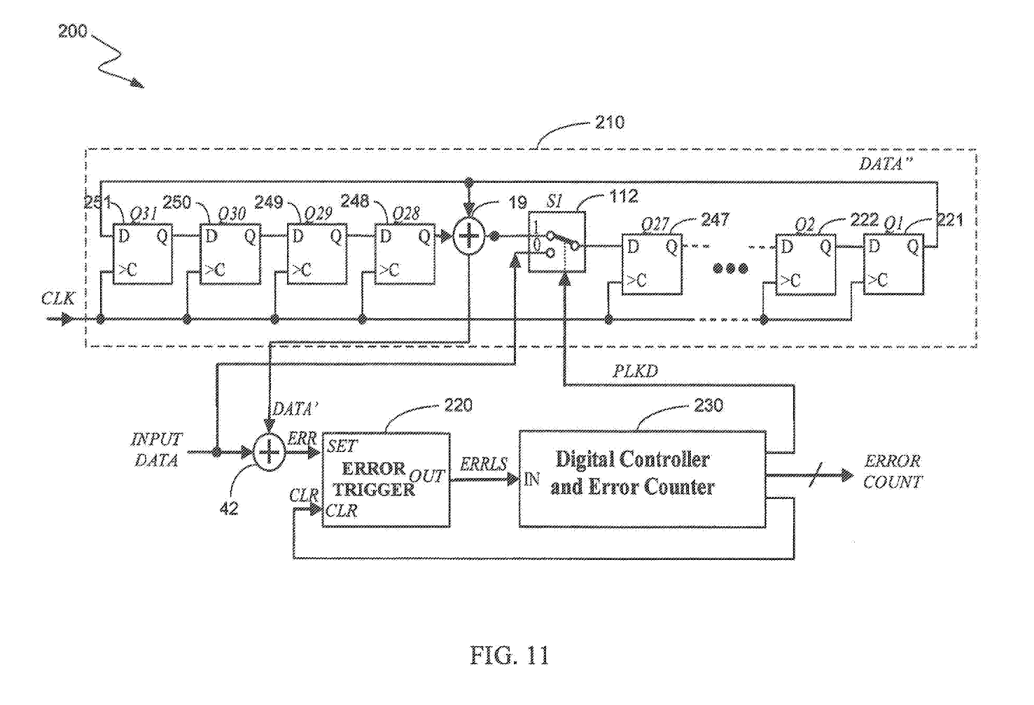

For example, FIG. 11 illustrates a block diagram of the pattern generator, error detector and error counter circuit 200 in accordance with another illustrative embodiment where N=31 and a generation polynomial of X³¹+X²⁸+1 is used. The pattern generator 210 is identical to the pattern generator 110 shown in FIG. 5, except that the pattern generator 210 has thirty-one registers 221-251 instead of the seven registers 12-18 shown in FIG. 5. The pattern generator 210 can even become more complex to combine multiple different generation polynomials. The error trigger block 220 and the digital controller and error counter block 230 shown in FIG. 11 may be identical to the error trigger block 120 and the digital controller and error counter block 130, respectively, shown in FIG. 5.

There are many other variations that may be made to PRBS-N pattern generator, error detector and error counter circuits described above with reference to FIGS. 5-11. In the signal of the PRBS-N generators, the data outputs from the last mod-2 adder to the last register right before the mod-2 adders are actually same except the clock latency. For example, the MUX 112 shown in FIG. 5 does not have to be inserted right after the mod-2 adder 19. Rather, it can be located at any node in the signal path between the output node of the mod-2 adder 19 to the input node of register Q1 12.

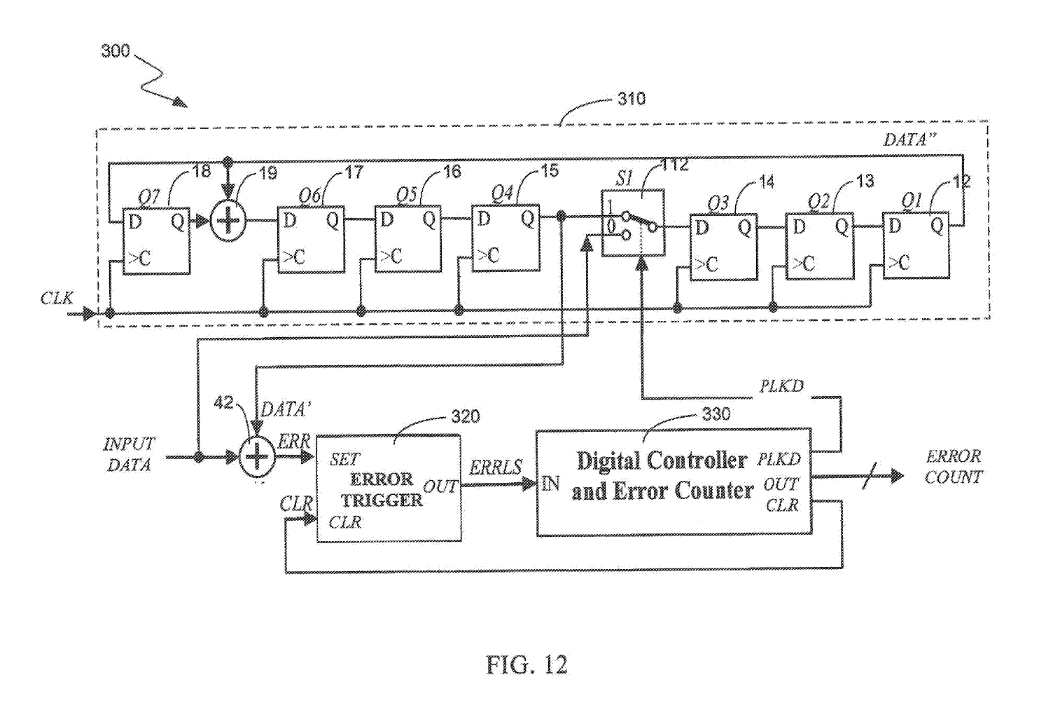

FIG. 12 illustrates a block diagram of the pattern generator, error detector and error counter circuit 300 in accordance with another illustrative embodiment. The circuit 300 includes a PRBS-7 pattern generator 310 that is identical to the PRBS-7 pattern generator 110 shown in FIG. 5 except that the MUX 112 of the PRBS-7 pattern generator 310 is located in between the output node of register 15 and the input node of register 14. The error trigger block 320 and the digital controller and error counter block 330 shown in FIG. 12 may be identical to the error trigger block 120 and the digital controller and error counter block 130, respectively, shown in FIG. 5. The circuit 300 operates in the manner described above with reference to FIGS. 5 and 6, and therefore will not be described in further detail herein.

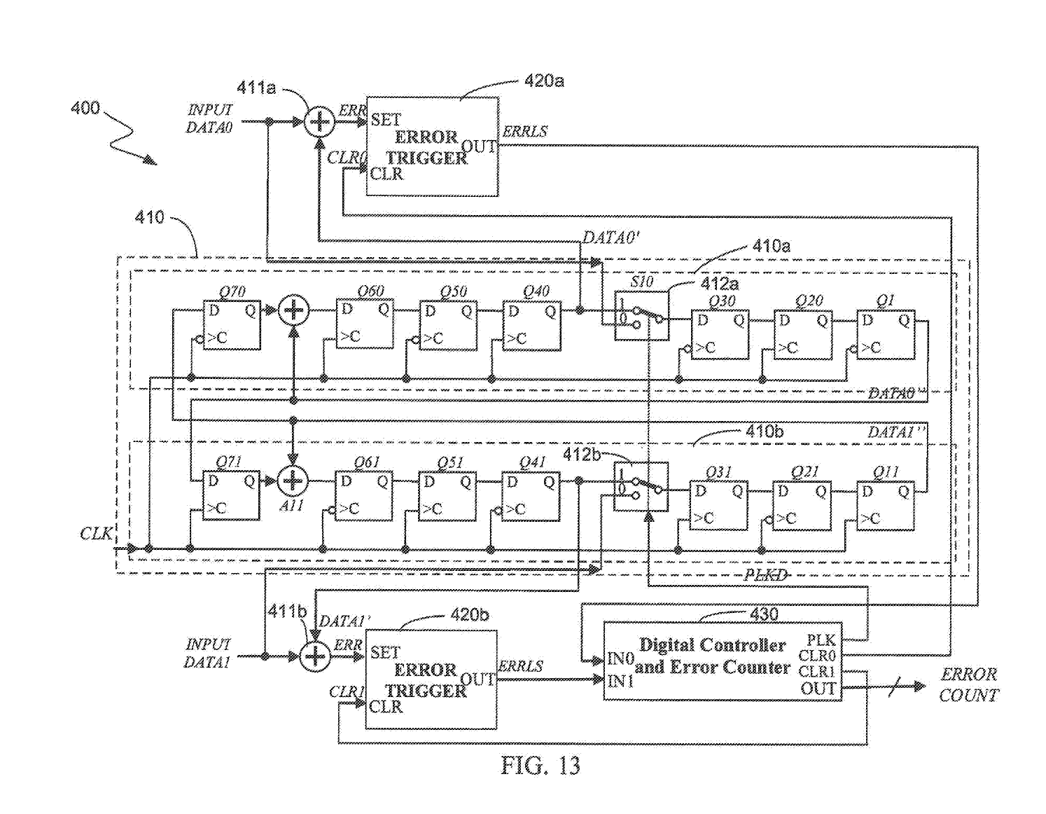

In the above illustrative embodiments, it is assumed that the data is clocked by a full rate clock having a frequency that is equal to the data rate. In those cases, there is one bit of data available per clock cycle of the full rate clock. In many data communications systems, however, the clock is sub-data rate, i.e., the clock has a frequency that is less than the data rate. The frequency of a sub-data rate clock is equal to the data rate divided by some positive integer, M, where M is greater than one. Therefore, there are M bits of data in one clock cycle of an M sub-rate data clock. It is not difficult to convert the circuits 100, 200 or 300 similar circuits of the M sub-rate clock variant, as will now be described with reference to FIG. 13.

FIG. 13 illustrates a block diagram of a PRBS-7 pattern generator, error detector and error counter circuit 400 in accordance with another illustrative embodiment in which a sub-rate clock is used, where M=2. An M=2 sub-rate clock is commonly referred to as a half-rate clock. A half-rate clock is currently the most popular clock strategy in high-speed data communications systems. The circuit 400 has two data inputs, INPUT DATA0 and INPUT DATA1. Because the clock CLK is one-half the data rate, two sets of hardware running at one-half the data rate, i.e., clocked by CLK, are used to perform pattern generation and error detection. Specifically, two seven-bit registers 410a and 410b are used in the PRBS-7 pattern generator 410. In addition, two mod-2 adders 411a and 411b are used to perform the respective bit comparisons and two error trigger blocks 420a and 420b are used to perform the error detection process. A single digital controller and error counter block 430 having logic for performing all of the control and bit counting operations is used in the circuit 400.

The PRBS-7 pattern generator 410 operates in the manner described above with reference to FIGS. 5 and 6. Likewise, each of the error trigger blocks 420a and 420b operates in the manner described above with reference to FIGS. 5 and 6. The digital controller and error counter block 430 operates in the manner described above with reference to FIGS. 5, 6, 9 and 10, except that it has logic in addition to what is shown in FIG. 9 to allow it to perform additional control and error counting operations associated with the two MUXes 412a and 412b and the two error trigger blocks 420a and 420b.

For example, block 430 shown in FIG. 12 may be implemented using a pair of the error counter blocks 160 and a pair of the BER calculator blocks 161 shown in FIG. 9 in combination with the single digital controller block 162 shown in FIG. 9. In all other respects, the PRBS-7 pattern generator, error detector and error counter circuit 400 operates in the same manner as the PRBS-7 pattern generator, error detector and error counter circuit 100 described above with reference to FIGS. 5-10. It should be noted that the invention has been described with reference to illustrative embodiments for the purpose of demonstrating principles and concepts of the invention. As will be understood by those skilled in the art in view of the description being provided herein, many modifications may be made to the embodiments described herein while still achieving the goals of the invention, and all such modifications are within the scope of the invention. For example, sub-rates that are less than half-rate may be used with additional sets of hardware operating in parallel with each set of hardware being driven by one phase of the clock. Also, although particular circuit configurations have been shown and described herein, other circuit configurations may be used to achieve the goals described herein, as will be understood by persons of skill in the art in view of the description provided herein.

What is claimed is:

1. A pseudo-random binary sequence (PRBS) pattern generator, error detector and counter circuit comprising:
an input data port that receives a multi-bit input data signal;
a PRBS pattern generator that is electrically coupled to the input data port;
an error detector electrically coupled to the input data port, the error detector detecting if mismatches occur between bits output from the PRBS pattern generator and respective bits of the multi-bit input data signal received at the input data port, wherein the error detector outputs an output signal from an output node thereof having a state that indicates whether or not a mismatch has been detected; and
a controller and error counter electrically coupled to the error detector and to the PRBS pattern generator, the controller and error counter outputting a control signal to the PRBS pattern generator to cause the PRBS pattern generator to either enter an initialization mode of operations or a comparison mode of operations, wherein during the initialization mode of operations, N bits of the multi-bit input data signal are loaded into the PRBS pattern generator, where N is a number of bits in a PRBS pattern, and wherein during the comparison mode of operations, the error detector detects if mismatches occur between bits output from the PRBS pattern generator and respective bits of the multi-bit input data signal, and wherein the controller and error counter counts the number of mismatches that are detected.

2. The PRBS pattern generator, error detector and counter circuit of claim 1, wherein the controller and error counter operates at a lower rate than a data rate of the multi-bit input data signal.

3. The PRBS pattern generator, error detector and counter circuit of claim 2, wherein the controller and error counter operates at a lower rate than a rate at which the PRBS pattern generator operates.

4. The PRBS pattern generator, error detector and counter circuit of claim 1, wherein during the comparison mode of operations, the controller and error counter determines a bit error rate (BER) corresponding to the number of mismatches that have occurred over time and compares the BER to a first predetermined threshold level to determine whether the PRBS pattern generator needs to be reinitialized.

5. The PRBS pattern generator, error detector and counter circuit of claim 4, wherein if the controller and error counter determines that the PRBS pattern generator needs to be reinitialized, the controller and error counter switches the PRBS pattern generator, error detector and error counter circuit from the comparison mode of operations to the initialization mode of operations to cause the PRBS pattern generator to be reinitialized by loading N bits of the multi-bit input data signal into the PRBS pattern generator.

6. The PRBS pattern generator, error detector and counter circuit of claim 5, wherein after the controller and error counter has caused the PRBS pattern generator to be reinitialized, the controller and error counter causes the PRBS pattern generator, error detector and error counter circuit to exit the initialization mode of operations and re-enter the comparison mode of operations.

7. The PRBS pattern generator, error detector and counter circuit of claim 1, wherein the PRBS pattern generator comprises:
a shift register comprising N registers, each register having an input node, an output node and a clock signal node;
a first modulo-2 (mod-2) adder employed in the shift register in between an output node of a first register of the N registers and an input node of a second register of the N registers, the first mod-2 adder having first and second input nodes and an output node; and
a switch employed in the shift register in between the output node of the first mod-2 adder and the input node of the second register, the switch having first and second input nodes, an output node and a control node, the first input node of the switch being connected to the output node of the first mod-2 adder, the second input node of the switch being connected to the input data port.

8. The PRBS pattern generator, error detector and counter circuit of claim 7, wherein the error detector comprises:
a second mod-2 adder having first and second input nodes and an output node, the first input node of the second mod-2 adder being connected to the input data port for receiving the multi-bit input data signal, the second input node of the second mod-2 adder being connected to the output node of the first mod-2 adder for receiving an output signal outputted from the first mod-2 adder; and
an error trigger having a set node, a clear node and an output node, the set node of the error trigger being connected to the output node of the second mod-2 adder, and wherein an input node of the controller and error counter is connected to the output node of the error trigger, and wherein a first output node of the controller and error counter is connected to the control node of the switch.

9. The PRBS pattern generator, error detector and counter circuit of claim 8, wherein the controller and error counter causes the PRBS pattern generator, error detector and error counter circuit to enter the initialization mode of operations by outputting a deasserted control signal to the control node of the switch to cause the switch to connect the second input node of the switch to the output node of the switch such that the multi-bit input data signal is applied to the input node of the second register, wherein the initialization mode of operations continues until a clock signal received at the clock signal nodes of the registers has caused N bits of the multi-bit input data signal to be shifted into the N registers, respectively.

10. The PRBS pattern generator, error detector and counter circuit of claim 9, wherein the initialization mode of operations aligns the N-bit PRBS pattern produced by the PRBS pattern generator with the multi-bit input data signal.

11. The PRBS pattern error detector and counter of claim 9, wherein the controller and error counter operates at a lower frequency than a frequency of the clock signal received at the clock signal nodes of the registers.

12. The PRBS pattern generator, error detector and counter circuit of claim 9, wherein the controller and error counter causes the PRBS pattern generator, error detector and error counter circuit to exit the initialization mode of operations and enter the comparison mode of operations by outputting an asserted control signal to the control node of the switch to cause the switch to connect the first input node of the switch to the output node of the switch such that bit values contained in the respective registers are shifted through the shift register as the clock signal received at the clock signal nodes of the registers clocks the registers, and wherein during the comparison mode of operations, the first mod-2 adder performs an exclusive OR operation on a bit output from the first register and a bit output from a third register of the N registers to produce an output bit of the PRBS pattern generator at the output node of the first mod-2 adder, and wherein during the comparison mode of operations, the second mod-2 adder performs an exclusive OR operation on the output bit of the PRBS pattern generator and a bit of the multi-bit input data signal to produce an output bit of the second mod-2 adder, and wherein the output bit of the second mod-2 adder is received at the set node of the error trigger.

13. The PRBS pattern generator, error detector and counter circuit of claim 12, wherein if the output bit of the second mod-2 adder is asserted, a mismatch has occurred between the bits that were exclusively ORed by the second mod-2 adder, wherein a mismatch causes the error trigger to output an asserted error signal from the output terminal of the error trigger to the input terminal of the controller and error counter.

14. The PRBS pattern generator, error detector and counter circuit of claim 13, wherein if the output bit of the second mod-2 adder is deasserted, a match has occurred between the bits that were exclusively ORed by the second mod-2 adder, wherein a match causes the error trigger to output a deasserted error signal from the output terminal of the error trigger to the input terminal of the controller and error counter.

15. The PRBS pattern generator, error detector and counter circuit of claim 8, wherein the error trigger captures and holds the error signal for multiple cycles of the clock signal until the controller and error counter has had sufficient time to process the error signal, and wherein the controller and error counter counts a number of times that the error signal received at the input node of the controller and error counter was asserted to produce an error count that is output from the second output node of the controller and error counter.

16. The PRBS pattern generator, error detector and counter circuit of claim 15, wherein the third output node of the controller and error counter is connected to the clear node of the error trigger, and wherein after the controller and error counter has had sufficient time to process an asserted error signal and produce an error count, the controller and error counter outputs a reset signal from the third output node of the controller and error counter to the clear node of the error trigger to cause a state of the error trigger to be reset, wherein resetting of the state of the error trigger deasserts the error signal output from the output node of the error trigger.

17. The PRBS pattern generator, error detector and counter circuit of claim 16, wherein the controller and error counter uses the error count to generate a bit error rate (BER) and determines whether the BER is above a predetermined threshold value, wherein if the controller and error counter determines that the BER is above the predetermined threshold value, the controller and error counter reenters the initialization mode of operations and outputs the deasserted control signal to the control node of the switch to cause the switch to connect the second input node of the switch to the output node of the switch such that the multi-bit input data signal is applied to the input node of the second register, wherein the initialization mode of operations continues until N bits of the multi-bit input data signal have been shifted into the N registers, respectively.

18. A pseudo-random binary sequence (PRBS) pattern generator, error detector and counter circuit comprising:
a PRBS pattern generator comprising:
a shift register comprising N registers, each register having an input node, an output node and a clock signal node,
a first bit comparator disposed in between an output node of one of the registers and an input node of another of the registers, and
a 2-to-1 multiplexer (MUX) disposed in between an output node of the first bit comparator and the input node of one of the registers, a first input node of the MUX being connected to the output node of the first bit comparator, a second input node of the MUX being connected to the input data port, an output node of the MUX being connected to the input node of said another of the registers;
an error detector comprising:
a second bit comparator, a first input node of the second bit comparator being connected to the input data port for receiving the multi-bit input data signal, a second input node of the second bit comparator being connected to the output node of the first bit comparator for receiving an output signal outputted from the first bit comparator, and
an error trigger, a set node of the error trigger being connected to the output node of the second bit comparator; and
a controller and error counter, wherein an input node of the controller and error counter is connected to an output node of the error trigger, and wherein a first output node of the controller and error counter is connected to a control node of the MUX, the controller and error counter controlling operations of the PRBS pattern generator and of the error detector based on a state of an error trigger output signal output from the error trigger and received by the controller and error counter.

19. The PRBS pattern generator, error detector and counter circuit of claim 18, wherein the controller and error counter operates at a slower speed than the PRBS pattern generator and error detector.

20. The PRBS pattern generator, the error detector and counter circuit of claim 19, wherein the error trigger asserts the state of the error trigger output signal when a bit error is detected, and wherein the error trigger maintains the asserted state of the error trigger output signal for a time period that is sufficiently long for the controller and error counter to process the bit error.

21. The PRBS pattern generator, the error detector and counter circuit of claim 19, wherein the controller and error counter outputs a control signal from the first output node of the control and error counter to the control node of the MUX to control the operations of the PRBS pattern generator, the error detector and counter circuit of claim

22. A method for performing pseudo-random binary sequence (PRBS) pattern generation, bit error detection and bit error counting comprising:
placing a PRBS pattern generator in an initialization mode of operations to cause N bits of a multi-bit input data signal to be loaded into N respective registers of a shift register of the PRBS pattern generator;
after the N bits have been loaded into the shift register, placing the PRBS pattern generator in a comparison mode of operations;
during the comparison mode of operations, comparing an output bit outputted from the PRBS pattern generator with a received bit of the multi-bit input data signal to determine if a mismatch occurs;
with a bit error counter, if a mismatch occurs, counting the mismatch as a bit error to generate a bit error count;
in a controller, using the bit error count to determine a bit error rate (BER);
in the controller, determining whether the BER exceeds a predetermined threshold value, and if so, returning the PRBS pattern generator to the initialization mode of operations to reinitialize the PRBS pattern generator, wherein the PRBS pattern generator is reinitialized by loading N bits of a multi-bit input data signal into N respective registers of the shift register; and
in the controller, after the PRBS pattern generator has been reinitialized, returning the PRBS pattern generator to the comparison mode of operations.
